(19) United States
(12) Patent Application Publication
(10) Pub. No.: US 2009/0065812 A1
(43) Pub. Date: Mar. 12, 2009

(54) COMPOUND SEMICONDUCTOR SUBSTRATE

(75) Inventors: Yoshihisa ABE, Hadano City (JP); Jun Komiyama, Hadano City (JP); Shunichi Suzuki, Hadano City (JP); Hiroshi Oishi, Hadano City (JP); Akira Yoshida, Hadano City (JP); Hideo Nakanishi, Hadano City (JP)

Correspondence Address: FOLEY AND LARDNER LLP;SUITE 500, 3000 K STREET NW, WASHINGTON, DC, 20007, US

(73) Assignee: COVALENT MATERIALS CORPORATION

(21) Appl. No.: 12/204,328

(22) Filed: Sep. 4, 2008

(30) Foreign Application Priority Data
Sep. 11, 2007 (JP) 2007-234972
Sep. 11, 2007 (JP) 2007-234973

(51) Int. Cl. H01L 29/205

(52) U.S. Cl. 257/201; 257/E29.091

(57) ABSTRACT

Provides is a compound semiconductor substrate about which the thickness of its nitride semiconductor single crystal layer can be made large while the generation of cracks, crystal defects or the like is restrained in the nitride semiconductor single crystal layer. The substrate has a first intermediate layer 110 formed on a Si single crystal substrate 100 having a crystal plane orientation of {111}. In the layer 110, a first metal compound layer 110a made of any one of TiC, TiN, VC and VN, and a second metal compound layer 110b made of any one of compounds which are different from the compound of the first metal compound layer out of TiC, TiN, VC and VN are laminated in this order alternately each other over the Si single crystal.

### BACKGROUND OF THE INVENTION

1. Field of the Invention

The present invention relates to a compound semiconductor substrate used preferably for a light emitting device or an electronic device.

2. Description of the Related Art

Nitride semiconductors, typical examples of which include gallium nitride (GaN) and aluminum nitride (AlN), have been expected to be applied to light emitting devices, electronic devices which can be operated at a high speed and at a high temperature, and other devices since the semiconductors have excellent properties such as high electron mobility and high heat resistance.

Conventionally, for a substrate which constitutes such a nitride semiconductor, sapphire, silicon (Si), zinc oxide (ZnO) and so on have been used. In these substrates, a Si single crystal substrate is better in crystallinity and can be produced into a larger area with a higher purity at lower costs than other substrates. Thus, the single crystal substrate is preferably used.

Additionally, when a Si single crystal substrate is used, the device step subsequent to the producing step thereof may be the present device step itself. For this reason, the Si single crystal substrate predominates from the viewpoint of development costs also. Thus, the Si single crystal substrate has been desired to be put into practical use.

However, when the thermal expansion coefficient of a Si single crystal substrate is compared with that of a nitride semiconductor, the nitride semiconductor has an about 2 times higher value than the Si single crystal substrate. Therefore, tensile stress is generated in a single crystal layer of the nitride semiconductor so that the layer is cracked. Furthermore, crystal defects are generated on the factor of a difference between the crystal lattice constant of Si and that of the nitride semiconductor.

Thus, known is a technique of forming, on a Si single crystal substrate, a nitride semiconductor single crystal layer so as to interpose an intermediate layer made of 3C—SiC or AlN therebetween (for example, JP-A-2006-216576 (Patent Document 1)).

Even in the case of forming a nitride semiconductor single crystal layer with the interposed intermediate layer described in this Patent Document 1, which is made of 3C—SiC or AlN, it was difficult to form the nitride semiconductor single crystal layer into a thickness of 1 μm or more from the viewpoint of the above-mentioned cracks or crystal defects, and others.

The crystallinity of a nitride semiconductor single crystal layer is a very important factor for improving the light emitting efficiency or the luminance of a light emitting device or improving the device characteristic of an electronic device.

An improvement in the crystallinity of a nitride semiconductor single crystal layer can be attained by making the film thickness thereof large. However, it was difficult to make the nitride semiconductor single crystal layer thick since cracks or crystal defects as described above cannot be restrained.

As a nitride-based light emitting element having a high light emitting efficiency, a low operation voltage and an excellent heat emitting efficiency, suggested is a nitride-based light emitting element having, on a substrate containing sapphire, silicon, zinc oxide or gallium arsenide, the following: a seed material layer made of a metal, an oxide, a nitride, a carbide or the like; a polyfunctional substrate containing Al—O, Al—N, Al—N-o or the like; a low-temperature buffer layer made of a good-quality element in the group III and nitrogen and grown in an atmosphere of hydrogen and ammonia gases at a temperature of 600° C. or lower; and a single crystal nitrogen-based multi-layered thin film grown in a reducing atmosphere such as hydrogen and ammonia gases at a temperature of 1000° C. or higher, or a light emitting structure, for light emitting element, wherein an n-type nitride-based clad layer, a nitride-based active layer and a p-type nitride-based clad layer are successively laminated on the nitride-based low-temperature buffer layer (JP-A-2007-53373 (Patent Document 2)).

Incidentally, the invention described in Patent Document 2 is an invention for preventing mechanical and thermal deformations and decomposition that are generated from the upper portion of a substrate, and is not an invention for forming a nitride semiconductor single crystal layer into a large thickness while the generation of cracks or crystal defects is prevented, as described above.

Even when various materials are used for the seed material layer and the polyfunctional substrate described in Patent Document 2, there is generated a limit to the restraint of the generation of cracks, crystal defects or the like, which follows the matter that the nitride semiconductor single crystal layer is made into a large thickness.

### SUMMARY OF THE INVENTION

The invention has been made to solve the above-mentioned technical problems, and an object thereof is to provide a compound semiconductor substrate about which the thickness of its nitride semiconductor single crystal layer can be made large while the generation of cracks, crystal defects or the like is restrained in the nitride semiconductor single crystal layer.

The compound semiconductor substrate of the invention comprises: a first intermediate layer formed on a Si single crystal substrate having a crystal plane orientation of a {111} plane, wherein the first intermediate layer comprises a first metal compound layer made of any one of TiC, TiN, VC and VN and a second metal compound layer made of any one of compounds which are different from the compound of the first metal compound layer out of TiC, TiN, VC and VN, the first metal compound layer and the second metal compound layer are laminated in this order alternately each other over the Si single crystal substrate, and the topmost layer of the resultant laminate is made of one of the first metal compound layers, or one of the second metal compound layers; a second intermediate layer formed on the first intermediate layer and made of In_{w}GaₓAl_{1-w-x}N single crystal wherein 0≦w<1, 0≦x<1, and w+x<1; and a nitride semiconductor single crystal layer formed on the second intermediate layer and made of In_{y}Ga_{z}Al_{1-y-z}N single crystal wherein 0≦y<1, 0≦Z<1, and y+z<1.

This structure makes it possible that while the generation of cracks, crystal defects or the like is restrained in the nitride semiconductor single crystal layer, the thickness of the nitride semiconductor single crystal layer is made large.

The compound semiconductor substrate of the invention also comprises: a 3C—SiC single crystal layer formed on a Si single crystal substrate having a crystal plane orientation of a {111} plane; a first intermediate layer formed on the 3C—SiC single crystal layer, wherein the first intermediate layer comprises a first metal compound layer made of any one of TiC, TiN, VC and VN and a second metal compound layer made of any one of compounds which are different from the compound of the first metal compound layer out of TiC, TiN, VC and VN, the first metal compound layer and the second metal compound layer are laminated in this order alternately each other over the Si single crystal substrate, and the topmost layer of the resultant laminate is made of one of the first metal compound layers, or one of the second metal compound layers; a second intermediate layer formed on the first intermediate layer and made of In_{w}GaₓAl_{1-w-x}N single crystal wherein 0≦w<1, 0≦x<1, and w+x<1; and a nitride semiconductor single crystal layer formed on the second intermediate layer and made of In_{y}Ga_{z}Al_{1-y-z}N single crystal wherein 0≦y<1, 0≦Z<1, and y+z<1.

This structure makes it possible that while the generation of cracks, crystal defects or the like is restrained in the nitride semiconductor single crystal layer, the thickness of the nitride semiconductor single crystal layer is made large.

It is preferred that the topmost layer is made of either TiC or VC.

This structure makes it possible that when this compound semiconductor substrate is used as a light emitting device, the light emitting efficiency and the luminance thereof are improved.

It is more preferred that the first metal compound layers are made of TiC, and the second metal compound layers are made of VC.

This structure makes it possible that when this compound semiconductor substrate is used as a high-luminance light emitting device, the light emitting efficiency and the luminance thereof are improved as well.

The compound semiconductor substrate of the invention also comprises: a first intermediate layer formed on a Si single crystal substrate having a crystal plane orientation of a {111} plane, wherein the first intermediate layer comprises a 3C—SiC single crystal layer and a metal compound layer made of any one of TiC, TiN, VC and VN, the 3C—SiC single crystal layer and the metal compound layer are laminated in this order alternately each other over the Si single crystal substrate, and the topmost layer of the resultant laminate is made of one of the 3C—SiC single crystal layers, or one of the metal compound layers; a second intermediate layer formed on the first intermediate layer and made of In_{w}GaₓAl_{1-w-x}N single crystal wherein 0≦w<1, 0≦x<1, and w+x<1; and a nitride semiconductor single crystal layer formed on the second intermediate layer and made of In_{y}Ga_{z}Al_{1-y-z}N single crystal wherein 0≦y<1, 0≦Z<1, and y+z<1.

This structure makes it possible to restrain the generation of cracks, crystal defects or the like in the nitride semiconductor single crystal layer and further improve the crystallinity of the nitride semiconductor single crystal layer.

It is preferred that the topmost layer is one of the metal compound layers.

This structure makes it possible that when this compound semiconductor substrate is used as a light emitting device, the light emitting efficiency and the luminance thereof are improved.

It is more preferred that the metal compound layers are made of either TiC or VC.

This structure makes it possible that when this compound semiconductor substrate is used as a light emitting device, the light emitting efficiency and the luminance thereof are further improved.

The compound semiconductor substrate of the invention also comprises: a first intermediate layer formed on a Si single crystal substrate having a crystal plane orientation of a {111} plane, wherein the first intermediate layer comprises a 3C—SiC single crystal layer, a first metal compound layer made of any one of TiC, TiN, VC and VN, and a second metal compound layer made of any one of compounds which are different from the compound of the first metal compound layer out of TiC, TiN, VC and VN, the 3C—SiC single crystal layer, the first metal compound layer and the second metal compound layer are laminated in this order alternately to one another over the Si single crystal substrate, and the topmost layer of the resultant laminate is made of one of the 3C—SiC single crystal layers, one of the first metal compound layers, or one of the second metal compound layers; a second intermediate layer formed on the first intermediate layer and made of In_{w}GaₓAl_{1-w-x}N single crystal wherein 0≦w<1, 0≦x<1, and w+x<1; and a nitride semiconductor single crystal layer formed on the second intermediate layer and made of In_{y}Ga_{z}Al_{1-y-z}N single crystal wherein 0≦y<1, 0≦Z<1, and y+z<1.

This structure makes it possible to restrain the generation of cracks, crystal defects or the like in the nitride semiconductor single crystal layer and further improve the crystallinity of the nitride semiconductor single crystal layer.

It is preferred that the topmost layer is one of the first metal compound layers, or one of the second metal compound layers.

This structure makes it possible that when this compound semiconductor substrate is used as a light emitting device, the light emitting efficiency and the luminance thereof are improved.

It is more preferred that the first metal compound layers or the second metal compound layers are made of either TiC or VC.

This structure makes it possible that when this compound semiconductor substrate is used as a light emitting device, the light emitting efficiency and the luminance thereof are further improved.

The invention provides a compound semiconductor substrate about which the thickness of its nitride semiconductor single crystal layer can be made large while the generation of cracks, crystal defects or the like is restrained in the nitride semiconductor single crystal layer.

### BRIEF DESCRIPTION OF THE DRAWINGS

FIG. 1 is a sectional view illustrating a compound semiconductor substrate according to a first embodiment of the invention;

FIG. 2 is a sectional view illustrating a compound semiconductor substrate according to the first embodiment of the invention;

FIG. 3 is a sectional view illustrating a compound semiconductor substrate according to a second embodiment of the invention;

FIG. 4 is a sectional view illustrating a compound semiconductor substrate according to the second embodiment of the invention;

FIG. 5 is a sectional view illustrating a compound semiconductor substrate according to a third embodiment of the invention;

FIG. 6 is a sectional view illustrating a compound semiconductor substrate according to the third embodiment of the invention;

FIG. 7 is a sectional view illustrating a compound semiconductor substrate according to a fourth embodiment of the invention;

FIG. 8 is a sectional view illustrating a compound semiconductor substrate according to the fourth embodiment of the invention; and

FIG. 9 is a sectional view illustrating a compound semiconductor substrate according to the fourth embodiment of the invention.

### DESCRIPTION OF THE PREFERRED EMBODIMENTS

Embodiments of the compound semiconductor substrate according to the invention will be described in detail with reference to the attached drawings.

### First Embodiment

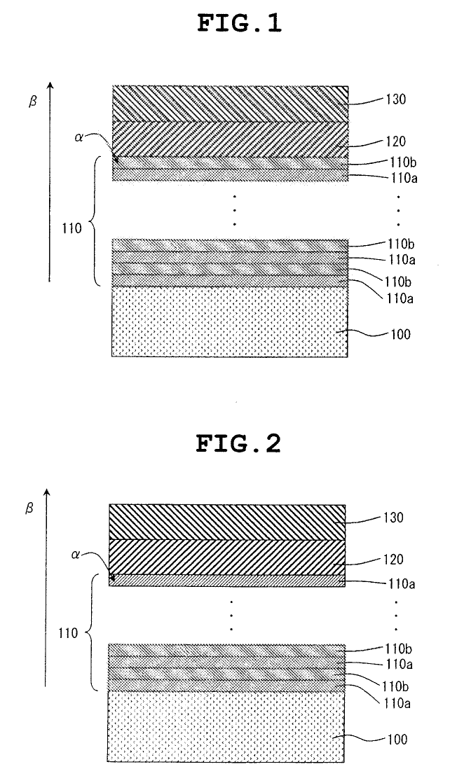

FIGS. 1 and 2 are each a sectional view illustrating a compound semiconductor substrate according to a first embodiment of the invention.

As illustrated in FIGS. 1 and 2, the compound semiconductor substrate according to the present embodiment has a structure which are successively formed a first intermediate layer 110, a second intermediate layer 120 and a compound semiconductor single crystal layer 130 on a Si single crystal substrate 100.

The Si single crystal substrate 100 is a Si single crystal substrate having a surface having a crystal plane orientation of a {111} plane. The plane orientation {111} may be a fine inclination (about more than ten degrees) of any normal crystal plane orientation {111}, or any one of crystal plane orientations having higher-order Miller indices, such as {211}. When the crystal plane orientation of the surface of the Si single crystal substrate 100 is made into {111} in this way, the generation of anti-phase boundary defects is decreased so that the concentration of an electric field into defects can be relieved.

The Si single crystal substrate 100 used in the invention is preferably a substrate produced by the CZ (Czochralski) method, but is not limited thereto. The Si single crystal substrate 100 may be a substrate produced by the FZ (floating zone) method, or a product wherein a Si single crystal layer is formed on a Si single crystal substrate produced by any one of these methods by vapor phase growth.

The Si single crystal substrate 100 may be, for example, a conductive n-type substrate having a carrier concentration of 10¹⁶ to 10²¹/cm³ (resistivity: about 1 to 0.00001 Ωcm).

As illustrated in FIG. 1 or 2, in the first intermediate layer 110, a first metal compound layer 110a and a second metal compound layer 110b are laminated, over the Si single crystal substrate, in this order repeatedly so as to alternate the resultant first metal compound layers 110a with the resultant second metal compound layers 110b and render the topmost layer α of the laminate one of the first metal compound layers 110a (FIG. 2) or one of the second metal compound layers 110b (FIG. 1).

In other words, when any first metal compound layers 110a and any second metal compound layers 110b are each counted as one layer, the first intermediate layer 110 according to the present embodiment is classified into the following two laminate structures: as illustrated in FIG. 1, a laminate structure made of layers the number of which is an even number except two, wherein a first metal compound layer 110a and a second metal compound layer 110b are laminated, over the Si single crystal substrate, in this order repeatedly and continuously so as to alternate the resultant first metal compound layers 110a with the resultant second metal compound layers 110b (the topmost layer α contacting the second intermediate layer 120 is one of the second metal compound layers 110b); and, as illustrated in FIG. 2, a laminate structure made of layers the number of which is an odd number except one, wherein a first metal compound layer 110a and a second metal compound layer 110b are laminated, over the Si single crystal substrate, in this order repeatedly and continuously so as to alternate the resultant first metal compound layers 110a with the resultant second metal compound layers 110b (the topmost layer α contacting the second intermediate layer 120 is one of the first metal compound layers 110a).

In short, when any one of the first metal compound layers 110a and any one of the second metal compound layers 110b are each counted as one layer, the word of the first intermediate layer 110 includes, in the concept thereof, “a laminate structure having three or more layers” but excludes, from the conception, a first intermediate layer 110 wherein only one of the first metal compound layers 110a and only one of the second metal compound layers 110b are formed, that is, a first intermediate layer 110 made only of the two layers.

The first metal compound layers 11a and the second metal compound layers 110b are made of any one of titanium carbide (TiC), titanium nitride (TiN), vanadium carbide (VC) and vanadium nitride (VN).

As a metal compound which can be used in an intermediate layer of a compound semiconductor substrate, the following can be supposed as disclosed in Patent Document 2 described above: an oxide, a nitride, a carbide or the like of Ti, Si, W, Co, Ni, Mo, Sc, Mg, Ge, Cu, Be, Zr, Fe, Al, Cr, Nb, Y, V or some other element.

As described in Patent Document 1 described above, 3C—SiC is preferably used as a compound which is able to be epitaxially grown on Si and further has the following characteristic: a layer made of GaN or AlN can be laminated on a layer made of this compound.

Any one of TiC, TiN, VC and VN described above has a thermal expansion coefficient and a crystal lattice constant similar to those of 3C—SiC, and can be preferably used as the material of the first metal compound layers 110a and that of the second metal compound layers 110b.

The metal compound which constitutes each of the first metal compound layers 110a is different from the metal compound which constitutes each of the second metal compound layers 110b. In other words, on any one of the first metal compound layers 110a each made of any one of TiC, TiN, VC and VN is laminated one of the second metal compound layers each made of any one of compounds which are different from the compound of the first metal compound layer out of TiC, TiN, VC and VN.

If the first metal compound layers 110a and the second metal compound layers 110b are made of the same metal compound in the laminate, it is very difficult to remove crystal defects for the following reason: for example, when a crystal defect is generated in one of the layers, the next layer, which is made of the same metal compound, inherits the crystal dislocation as it is therefrom.

Moreover, the layers made of the same metal compound substantially have a structure wherein a single layer is made thick; therefore, the above-mentioned cracks or the like is unfavorably generated from the first intermediate layer itself.

As understood from the above, the first intermediate layer 110 contains a structure wherein two metal compound layers different from each other, such as —TiC-VC—, —TiN-VC—, —TiC-VN— or —TiN—VN—, are repeatedly and continuously laminated, a structure wherein three metal compound layers different from each other, such as —TiC-VC—TiN—, or —TiN-VN—TiC—, are repeatedly and continuously laminated, or a structure wherein four metal compound layers different from each other, such as —TiC—VC—TiN—VN—, are repeatedly and continuously laminated.

Each of the first metal compound layers 110a preferably has a film thickness of 1 to 50 nm as well as each of the second metal compound layers 110b.

If the film thickness of the first metal compound layer 110a or the second metal compound layer 110b is less than 1 nm, the layer cannot function as one layer out of the first intermediate layer 110, wherein layers of different metal compounds are made into a laminate. If the film thickness is more than 50 nm, the above-mentioned strain, cracks or the like is unfavorably generated from the first or second metal compound layer itself.

The second intermediate layer 120 is formed on the first intermediate layer 110, and is made of In_{w}GaₓAl_{1-w-x}N single crystal wherein 0≦w<1, 0≦x<1, and w+x<1.

The film thickness of the second intermediate layer 120 preferably ranges from 1 to 200 nm. If the film thickness is less than 1 nm, the layer is too thin to function as an intermediate layer. If the film thickness is more than 200 nm, the above-mentioned cracks or the like is unfavorably generated from the second intermediate layer 120 itself.

The nitride semiconductor single crystal layer 130 is formed on the second intermediate layer 120 and made of In_{y}Ga_{z}Al_{1-y-z}N single crystal wherein 0≦y<1, 0≦Z<1, and y+z<1.

In_{w}GaₓAl_{1-w-x}N single crystal of the second intermediate layer 120 is preferably AlN (i.e., In_{w}GaₓAl_{1-w-x}N wherein w=0, x=0), and In_{y}Ga_{z}Al_{1-y-z}N single crystal of the nitride semiconductor single crystal layer 130 is preferably GaN (i.e., In_{y}Ga_{z}Al_{1-y-z}N wherein y=0 and z=1). The lattice constants of AlN and GaN are 3.112 Å (in terms of the a axis) and 3.18 Å, respectively, and the nitrides are small in lattice mismatch; therefore, when the nitrides are used, the generation of crystal defects generated by lattice mismatch (misfit dislocation defects) can be decreased.

The first intermediate layer 110, the second intermediate layer 120 and the nitride semiconductor single crystal layer 130 can be formed by, for example, CVD such as MOCVD (metal organic chemical vapor deposition) or PECVD (plasma enhanced chemical vapor deposition), vapor deposition using a laser beam, or sputtering using a reaction gas. In the invention, MOCVD is used.

As described above, the compound semiconductor substrate according to the present embodiment has a first intermediate layer wherein a first metal compound layer made of any one of TiC, TiN, VC and VN and a second metal compound layer made of any one of compounds which are different from the compound of the first metal compound layer out of TiC, TiN, VC and VN are laminated, over the Si single crystal substrate, in this order repeatedly, so as to alternate the first metal compound layers with the second metal compound layers and render the topmost layer of the resultant laminate one of the first metal compound layers, or one of the second metal compound layers.

When metal compounds different from each other out of TiC, TiN, VC and VN are used to laminate the first metal compound layers 110a and the second metal compound layers 110b in such a manner that the first metal compound layers 110a are alternated with the second metal compound layers 110b as described above, the generation of cracks, crystal defects and others can be restrained in the nitride semiconductor single crystal layer 130. Accordingly, the nitride semiconductor single crystal layer 130 can be made into a large thickness.

The topmost layer α is preferably made of either TiC or VC.

When a compound semiconductor substrate wherein Si single crystal is used as a substrate, as in the present embodiment, is used as a light emitting device, a well-known light emitting structure is usually formed on the Si single crystal substrate (not illustrated).

In the case of such a structure, the direction in which the structure is to emit light as a light emitting device is the direction of the laminating of the layers (β direction in FIGS. 1 and 2). However, light rays from the light emitting structure are emitted not only in the above-mentioned light emitting direction (the laminating direction β) but also the direction opposite to the light emitting direction (that is, the direction opposite to the laminating direction β).

In order for the structure in this case to make the light emitting efficiency high as a light emitting device, it is preferred to lay a reflective layer for reflecting light advancing in the opposite direction so as to advance in the light emitting direction beneath the light emitting structure, that is, in the laminate structure of the compound semiconductor substrate.

For reference, a metal compound layer made of any one of TiC, TiN, VC and VN has a higher function as a reflective layer (reflectivity) than the layer described in Patent Document 1, which is made of 3C—SiC. This is because 3C—SiC has a band gap of 2.2 eV and absorbs visible rays, which is different from TiC, TiN, VC and VN, which are each a metal compound. Out of TiC, TiN, VC and VN, TiC and VC have a higher function as a reflective layer (reflectivity) than TiN and VN.

Accordingly, when at least the topmost layer α, which functions as a reflective layer and contacts the second intermediate layer 120, out of the first intermediate layer 110 is made of either TiC or VC, the light emitting efficiency and the luminance can be further improved in the case of using this compound semiconductor substrate as a light emitting device.

It is more preferred that the first metal compound layers 110a are made of TiC and the second metal compound layers 110b are made of VC.

As described above, when at least the topmost layer α, which contacts the second intermediate layer 120, out of the first intermediate layer 110 is made of any one of TiC and VC, both of the light emitting efficiency and the luminance become higher than when the topmost layer α is made of TiN or VN. However, when the compound semiconductor substrate is used as a high-luminance light emitting device, emitted light becomes intense.

As a result, even if only the topmost layer α is made of any one of TiC and VC, which have high reflecting efficiency, it is feared that emitted light penetrates the topmost layer α to reach a layer beneath the topmost layer.

Against such a case, in a case where all layers out of the first intermediate layer 110 are made of any one of metal compounds of TiC and VC, emitted light can be certainly reflected even when the present device is a high-luminance light emitting device. For this reason, even when the present embodiment is used as a high-luminance light emitting device, the light emitting efficiency and the luminance can be improved.

In the embodiment, the number of the laminated layers in the first intermediate layer 110 is appropriately designed or modified in accordance with the thickness of the second intermediate layer 120 and the nitride semiconductor single crystal layer 130, and others. The film thickness of the nitride semiconductor single crystal layer 130 not permitting cracks, crystal defects or the like to be generated in the layer 130 cannot be specified without reservation since the film thickness depends on the number of the laminated layers in the first intermediate layer 110, and the thickness of the second intermediate layer 120 and the nitride semiconductor single crystal layer 130. The film thickness can be made into a large value of at most about 8.0 μm.

### Second Embodiment

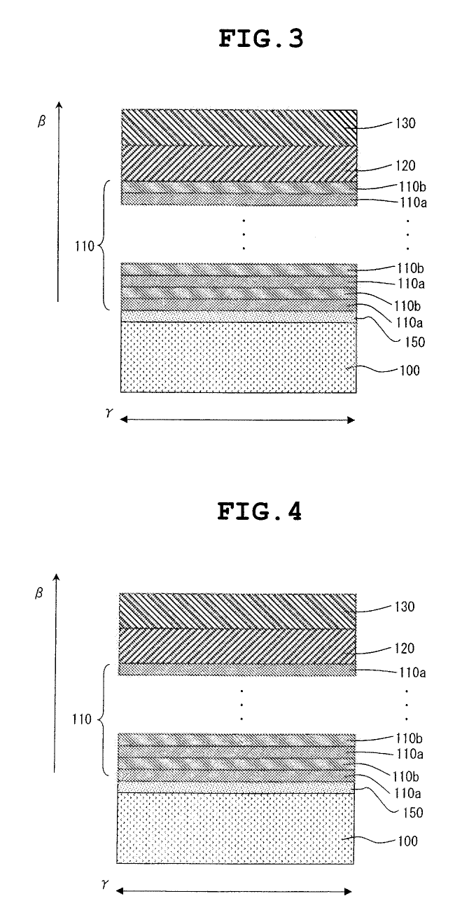

FIGS. 3 and 4 are each a sectional view illustrating a compound semiconductor substrate according to a second embodiment of the invention.

The compound semiconductor substrate according to the embodiment is different from the first embodiment in that a 3C—SiC single crystal layer 150 is formed between the first intermediate layer 110 and the Si single crystal substrate 100. Since the others are the same as in the first embodiment, description thereof is omitted.

Specifically, as illustrated in FIGS. 3 and 4, in the compound semiconductor substrate according to the embodiment, the 3C—SiC single crystal layer 150 is formed on the Si single crystal substrate, which has a crystal plane orientation of a {111} plane, and further the same first intermediate layer 110 as described in the first embodiment is formed on the 3C—SiC single crystal layer 150.

The film thickness of the 3C—SiC single crystal layer 150 preferably ranges from 10 to 800 nm. If the film thickness is less than 10 nm, the layer is too thin to function as an intermediate layer. If the film thickness is more than 800 nm, the above-mentioned cracks or the like is unfavorably generated from the single crystal layer itself.

In the case of such a structure, the lattice constant of any one of TiC, TiN, VC and VN, which constitutes the first intermediate layer 110, is smaller than that of 3C—SiC; therefore, crystal lattices made of any one of TiC, TiN, VC and VN are forced to be stretched (tensile stress) in layer directions (γ directions in FIG. 3). Reversely, crystal lattices made of 3C—SiC are forced to be shrunken in the layer directions γ. In other words, compressive stress acts onto the 3C—SiC single crystal layer 150. Additionally, the thermal expansion coefficient of any one of TiC, TiN, VC and VN is larger than that of 3C—SiC, so that compressive stress is further applied to the 3C—SiC single crystal layer 150.

As a result, the compressive stress in the 3C—SiC single crystal layer 150 acts to relieve the tensile stress in the first intermediate layer 110 on the layer 150. Furthermore, the compressive stress further relieves the second intermediate layer 120 thereon, and the nitride semiconductor single crystal layer 130 thereon in turn. Accordingly, the generation of cracks, crystal defects or the like in the nitride semiconductor single crystal layer 130 can be further restrained; thus, the nitride semiconductor single crystal layer 130 can be made into a larger thickness.

### Third Embodiment

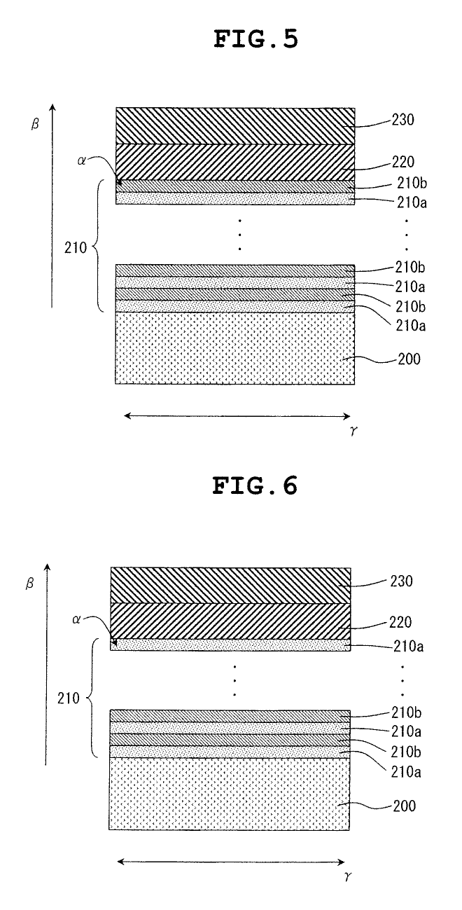

FIGS. 5 and 6 are each a sectional view illustrating a compound semiconductor substrate according to a third embodiment of the invention.

As illustrated in FIGS. 5 and 6, the compound semiconductor substrate according to the present embodiment has a structure which are successively formed a first intermediate layer 210, a second intermediate layer 220 and a compound semiconductor single crystal layer 230 on a Si single crystal substrate 200.

The Si single crystal substrate 200 may be identical to the Si single crystal substrate 100 described about the first embodiment.

As illustrated in FIG. 5 or 6, in the first intermediate layer 210, a 3C—SiC single crystal layer 210a and a metal compound layer 210b are laminated, over the Si single crystal substrate 200, in this order repeatedly so as to alternate the resultant 3C—SiC single crystal layers 210a with the resultant metal compound layers 210b and render the topmost layer α of the laminate one of the 3C—SiC single crystal layers (FIG. 6) or one of the metal compound layers 210b (FIG. 5).

In other words, when any 3C—SiC single crystal layers 210a and any metal compound layers 210b are each counted as one layer, the first intermediate layer 210 according to the present embodiment is classified into the following two laminate structures: as illustrated in FIG. 5, a laminate structure made of layers the number of which is an even number except two, wherein a 3C—SiC single crystal layer 210a and a metal compound layer 210b are laminated, over the Si single crystal substrate 200, in this order repeatedly and continuously so as to alternate the resultant 3C—SiC single crystal layers 210a with the resultant metal compound layers 210b (the topmost layer α contacting the second intermediate layer 220 is one of the metal compound layers 210b); and, as illustrated in FIG. 6, a laminate structure made of layers the number of which is an odd number except one, wherein a 3C—SiC single crystal layer 210a and a metal compound layer 210b are laminated, over the Si single crystal substrate 200, in this order repeatedly and continuously so as to alternate the resultant 3C—SiC single crystal layers 210a with the resultant metal compound layers 210b (the topmost layer α contacting the second intermediate layer 220 is one of the 3C—SiC single crystal layers 210a).

In short, when any one of the 3C—SiC single crystal layers 210a and any one of the metal compound layers 210b are each counted as one layer, the word of the first intermediate layer 210 includes, in the concept thereof, “a laminate structure having three or more layers” but excludes, from the conception, a first intermediate layer 210 wherein only one of the 3C—SiC single crystal layers 210a and only one of the metal compound layers 210b are formed, that is, a first intermediate layer 210 made only of the two layers.

Each of the 3C—SiC single crystal layers 210a is made of cubic 3C—SiC single crystal.

The 3C—SiC single crystal layer 210a preferably has a film thickness of 1 to 100 nm.

If the film thickness of the 3C—SiC single crystal layer 210a is less than 1 nm, the layer cannot function as one layer out of the first intermediate layer 210, wherein layers of different materials are made into a laminate. If the film thickness is more than 100 nm, the above-mentioned strain, cracks or the like is unfavorably generated from the 3C—SiC single crystal layer itself.

Each of the 3C—SiC single crystal layers 210a may be, for example, a conductive n-type layer having a carrier concentration of 10¹⁵ to 10²⁰/cm³.

Each of the metal compound layers 210b is made of any one of titanium carbide (TiC), titanium nitride (TiN), vanadium carbide (VC) and vanadium nitride (VN) in the same manner as each of the first metal compound layers 110a and the second metal compound layers 110b described in the first embodiment.

As a metal compound which can be used in an intermediate layer of a compound semiconductor substrate, the following can be supposed as disclosed in Patent Document 2 described above: an oxide, a nitride, a carbide or the like of Ti, Si, W, Co, Ni, Mc, Sc, Mg, Ge, Cu, Be, Zr, Fe, Al, Cr, Nb, Y, V or some other element.

As described in Patent Document 1 described above, 3C—SiC is preferably used as a compound which is able to be epitaxially grown on Si and further has the following characteristic: a layer made of GaN or AlN can be laminated on a layer made of this compound.

Any one of TiC, TiN, VC and VN described above has a thermal expansion coefficient and a crystal lattice constant similar to those of 3C—SiC, and can be preferably used as the material of the metal compound layers 210b.

Each of the metal compound layers 210b preferably has a film thickness of 1 to 50 nm.

If the film thickness of the metal compound layer 210b is less than 1 nm, the layer cannot function as one layer out of the first intermediate layer 210, wherein layers of different materials are made into a laminate. If the film thickness is more than 50 nm, the above-mentioned strain, cracks or the like is unfavorably generated from the metal compound layer itself.

The second intermediate layer 220 is formed on the first intermediate layer 210, specifically, on the topmost layer α out of the first intermediate layer 210, and is made of In_{w}GaₓAl_{1-w-x}N single crystal wherein 0≦w<1, 0≦x<1, and w+x<1 in the same manner as in the first embodiment.

The film thickness of the second intermediate layer 220 preferably ranges from 1 to 200 nm. If the film thickness is less than 1 nm, the layer is too thin to function as an intermediate layer. If the film thickness is more than 200 nm, the above-mentioned cracks or the like is unfavorably generated from the second intermediate layer 220 itself.

The nitride semiconductor single crystal layer 230 is formed on the second intermediate layer 220 and made of In_{y}Ga_{z}Al_{1-y-z}N single crystal wherein 0≦y<1, 0≦Z<1, and y+z<1 in the same way as in the first embodiment.

The first intermediate layer 210, the second intermediate layer 220 and the nitride semiconductor single crystal layer 230 may be formed by the same method as in the first embodiment.

As described above, the compound semiconductor substrate according to the present embodiment has a first intermediate layer wherein a 3C—SiC single crystal layer and a metal compound layer made of any one of TiC, TiN, VC and VN are laminated, over a Si single crystal substrate, in this order repeatedly, so as to alternate the 3C—SiC single crystal layers with the metal compound layers and render the topmost layer of the resultant laminate one of the 3C—SiC single crystal layers, or one of the metal compound layers.

The lattice constant of any one of TiC, TiN, VC and VN, which constitutes the metal compound layers 210b out of the first intermediate layer 210, is smaller than that of 3C—SiC; therefore, crystal lattices made of any one of TiC, TiN, VC and VN are forced to be stretched (tensile stress) in horizontal directions (γ directions in FIGS. 5 and 6). Reversely, crystal lattices made of 3C—SiC are forced to be shrunken in the horizontal directions γ. In other words, compressive stress acts onto the 3C—SiC single crystal layers 210a. Additionally, the thermal expansion coefficient of any one of TiC, TiN, VC and VN is larger than that of 3C—SiC, so that compressive stress is further applied to the 3C—SiC single crystal layers 210a. The compressive stress in the 3C—SiC single crystal layers 210a relieves the tensile stress in the second intermediate layer 220 over the layers 210a, and further relieves the tensile stress in the nitride semiconductor single crystal layer 230. Thus, such a structure makes it possible to restrain the generation of cracks, crystal defects or the like in the nitride semiconductor single crystal layer 230.

Moreover, by making the first intermediate layer 210 into such a structure, the 3C—SiC single crystal layers 210a can be accumulatively made into a large thickness in the first intermediate layer 210. As a result, the crystallinity of the 3C—SiC single crystal layers 210a can be improved so as to improve the crystallinity of the second intermediate layer 220 over the layers 210a, and that of the nitride semiconductor single crystal layer 230 in turn.

Accordingly, in the compound semiconductor substrate according to the present embodiment, the crystallinity of the nitride semiconductor single crystal layer 230 can be improved without making the nitride semiconductor single crystal layer 230 into a large thickness.

The topmost layer α is preferably one of the metal compound layers 210b.

The metal compound layers 210b are preferably made of either TiC or VC.

When a compound semiconductor substrate wherein Si single crystal is used as a substrate, as in the present embodiment, is used as a light emitting device, a well-known light emitting structure is usually formed on the Si single crystal substrate (not illustrated).

In the case of such a structure, the direction in which the structure is to emit light as a light emitting device is the direction of the laminating of the layers in the compound semiconductor substrate (β direction in FIGS. 5 and 6). However, light rays from the light emitting structure are emitted not only in the above-mentioned light emitting direction (the laminating direction β) but also the direction opposite to the light emitting direction (that is, the direction opposite to the laminating direction β).

In order for the structure in this case to make the light emitting efficiency high as a light emitting device, it is preferred to lay a reflective layer for reflecting light advancing in the opposite direction so as to advance in the light emitting direction beneath the light emitting structure, that is, in the laminate structure of the compound semiconductor substrate.

For reference, a metal compound layer made of any one of TiC, TiN, VC and VN has a higher function as a reflective layer (reflectivity) than the layer made of 3C—SiC. This is because 3C—SiC has a band gap of 2.2 eV and absorbs visible rays, which is different from TiC, TiN, VC and VN, which are each a metal compound. Out of TiC, TiN, VC and VN, TiC and VC have a higher function as a reflective layer (reflectivity) than TiN and VN.

Accordingly, when at least the topmost layer α, which functions as a reflective layer and contacts the second intermediate layer 220, out of the first intermediate layer 210 is made of any one of TiC, TiN, VC and VN, preferably either TiC or VC, the light emitting efficiency and the luminance can be further improved in the case of using this compound semiconductor substrate as a light emitting device.

Since the compound semiconductor substrate according to the present embodiment has the first intermediate layer 210 as described above, the nitride semiconductor single crystal layer 230 can be made thick within such a limitation that cracks, crystal defects or the like is not generated in the layer 230. When the nitride semiconductor single crystal layer 230 is made thick, the crystallinity of the layer itself can be improved.

In the embodiment, the number of the laminated layers in the first intermediate layer 210 is appropriately designed or modified in accordance with the thickness of the second intermediate layer 220 and the nitride semiconductor single crystal layer 230, and others. The film thickness of the nitride semiconductor single crystal layer 230 not permitting cracks, crystal defects or the like to be generated in the layer 230 cannot be specified without reservation since the film thickness depends on the number of the laminated layers in the first intermediate layer 210, and the thickness of the second intermediate layer 220 and the nitride semiconductor single crystal layer 230. The film thickness can be made into a large value of at most about 8.0 μm.

### Fourth Embodiment

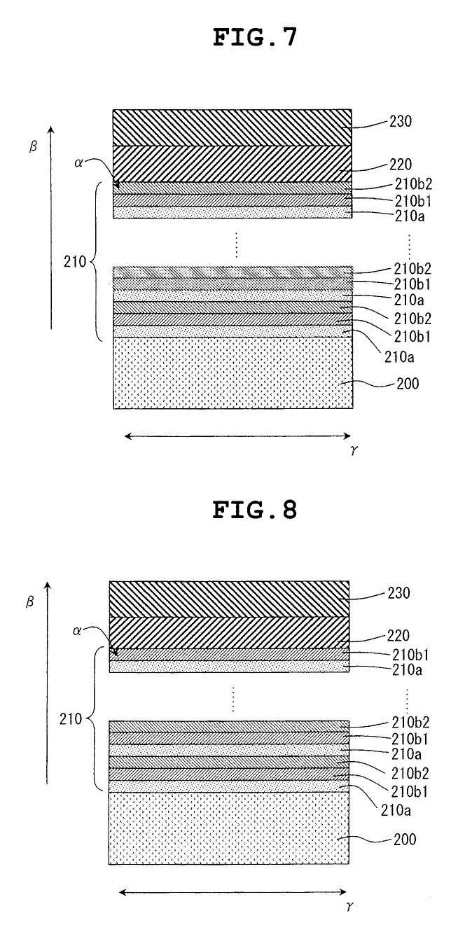

FIGS. 7 to 9 are each a sectional view illustrating a compound semiconductor substrate according to a fourth embodiment of the invention.

The compound semiconductor substrate according to the embodiment has a structure wherein each of the metal compound layers 210b according to the third embodiment is replaced with a first metal compound layer 210b1 and a second metal compound layer 210b2. Since the other constituents are the same as in the third embodiment, description thereof is omitted.

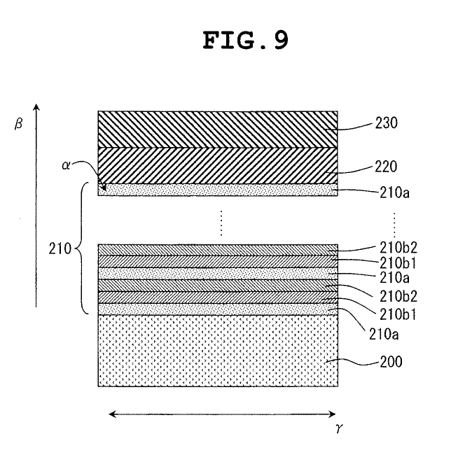

That is to say, as illustrated in FIGS. 7 to 9, the first intermediate layer 210 according to the embodiment is a layer wherein a 3C—SiC single crystal layer 210a, a first metal compound layer 210b1, and a second metal compound layer 210b2 are laminated, over a Si single crystal substrate 200, in this order repeatedly, and render the topmost layer of the resultant laminate one of the 3C—SiC single crystal layers 210a (FIG. 9), one of the first metal compound layers 210b1 (FIG. 8), or one of the second metal compound layers 210b2 (FIG. 7).

In other words, when any 3C—SiC single crystal layer 210a, any first metal compound layer 210b1, and any second metal compound layer 210b2 are each counted as one layer, the first intermediate layer 210 according to the present embodiment is classified into the following three laminate structures: as illustrated in FIG. 7, a laminate structure made of layers the number of which is 3n wherein n is 2, 3, . . . (so that the number is not 3), wherein a 3C—SiC single crystal layer 210a, a first metal compound layer 210b1, and a second metal compound layer 210b2 are laminated, over a Si single crystal substrate 200, in this order repeatedly and continuously so as to alternate the resultant 3C—SiC single crystal layers 210a with combinations of the first metal compound layer 210b1 and the second metal compound layer 210b2 (the topmost layer α contacting the second intermediate layer 220 is one of the second metal compound layers 210b2); as illustrated in FIG. 8, a laminate structure made of layers the number of which is 3n−1 wherein n is 2, 3, . . . (so that the number is not 2), wherein a 3C—SiC single crystal layer 210a, a first metal compound layer 210b1, and a second metal compound layer 210b2 are laminated, over a Si single crystal substrate 200, in this order repeatedly and continuously so as to alternate the resultant 3C—SiC single crystal layers 210a with combinations of the first metal compound layer 210b1 and the second metal compound layer 210b2 (the topmost layer α contacting the second intermediate layer 220 is one of the first metal compound layers 210b1); and, as illustrated in FIG. 9, a laminate structure made of layers the number of which is 3n−2 wherein n is 2, 3, . . . (so that the number is not 1), wherein a 3C—SiC single crystal layer 210a, a first metal compound layer 210b1, and a second metal compound layer 210b2 are laminated, over a Si single crystal substrate 200, in this order repeatedly and continuously so as to alternate the resultant 3C—SiC single crystal layers 210a with combinations of the first metal compound layer 210b1 and the second metal compound layer 210b2 (the topmost layer α contacting the second intermediate layer 220 is one of the 3C—SiC single crystal layers 210a).

In short, when any one of the 3C—SiC single crystal layers 210a, any one of the first metal compound layers 210b1 and any one of the second metal compound layers 210b2 are each counted as one layer, the word of the first intermediate layer 210 includes, in the concept thereof, “a laminate structure having four or more layers” but excludes, from the conception, a first intermediate layer 210 wherein only one of the 3C—SiC single crystal layers 210a, only one of the first metal compound layers 210b1, and only one of the second metal compound layers 210b2 are formed, that is, a first intermediate layer 210 made only of the three layers.

Each of the first metal compound layers 210b1 and the second metal compound layers 210b2 are made of any one of titanium carbide (TiC), titanium nitride (TiN), vanadium carbide (VC) and vanadium nitride (VN).

As a metal compound which can be used in an intermediate layer of a compound semiconductor substrate, the following can be supposed as disclosed in Patent Document 2 described above: an oxide, a nitride, a carbide or the like of Ti, Si, W, Co, Ni, Mo, Sc, Mg, Ge, Cu, Be, Zr, Fe, Al, Cr, Nb, Y, V or some other element.

As described in Patent Document 1 described above, 3C—SiC is preferably used as a compound which is able to be epitaxially grown on Si and further has the following characteristic: a layer made of GaN or AlN can be laminated on a layer made of this compound.

Anyone of TiC, TiN, VC and VN described above has a thermal expansion coefficient and a crystal lattice constant similar to those of 3C—SiC, and can be preferably used as the material of the first metal compound layers 210b1 and that of the second metal compound layers 210b2.

The metal compound which constitutes the first metal compound layers 210b1 is different from the metal compound which constitutes the second metal compound layers 210b2.

If the first metal compound layers 210b1 and the second metal compound layers 210b2 are made of the same metal compound in the laminate, the layers substantially become a structure wherein a single layer made of the metal compound is made thick; therefore, cracks or the like is unfavorably generated from the first metal compound layers 210b1 and the second metal compound layers 210b2 themselves.

In light of the above, the combination of the material of the first metal compound layers 210b1 and that of the second metal compound layers 210b2 is preferably a combination of TiC and VC, TiC and VN, TiN and VC, or TiN and VC.

Each of the first metal compound layers 210b1 preferably has a film thickness of 1 to 50 nm as well as each of the second metal compound layers 210b2.

If the film thickness of the first metal compound layer 210b1 or the second metal compound layer 210b2 is less than 1 nm, the layer cannot function as one layer out of the first intermediate layer 210, wherein layers of different metal compounds are made into a laminate. If the film thickness is more than 50 nm, the above-mentioned strain, cracks or the like is unfavorably generated from the first or second metal compound layer itself.

The lattice constant of any one of TiC, TiN, VC and VN, which constitute the first metal compound layers 210b1 and the second metal compound layers 210b2, is smaller than that of 3C—SiC; therefore, crystal lattices made of anyone of TiC, TiN, VC and VN are forced to be stretched (tensile stress) in horizontal directions (γ directions in FIGS. 7 to 9). Reversely, crystal lattices made of 3C—SiC are forced to be shrunken in the horizontal directions γ. In other words, compressive stress acts onto the 3C—SiC single crystal layers 210a. Additionally, the thermal expansion coefficient of any one of TiC, TiN, VC and VN is larger than that of 3C—SiC, so that compressive stress is further applied to the 3C—SiC single crystal layers 210a.

In the present embodiment, which is different from the third embodiment, its metal compound layers which cause compressive stress to be applied to the 3C—SiC single crystal layers 210a are provided layers of two kinds compared with the first embodiment. For this reason, a further compressive stress is applied to the 3C—SiC single crystal layers 210a.

The compressive force in the 3C—SiC single crystal layers 210a relieves tensile stress in the second intermediate layer 220 over the layers 210a, and that in the nitride semiconductor single crystal layer 230 in turn. Thus, such a structure makes it possible to restrain the generation of cracks, crystal defects or the like in the nitride semiconductor single crystal layer 230.

Moreover, by making the first intermediate layer 210 into such a structure, the 3C—SiC single crystal layers 210a can be accumulatively made into a large thickness in the first intermediate layer 210. As a result, the crystallinity of the 3C—SiC single crystal layers 210a can be improved so as to improve the crystallinity of the second intermediate layer 220 over the layers 210a, and that of the nitride semiconductor single crystal layer 230 in turn.

The topmost layer α is preferably one of the first metal compound layers 210b1 (FIG. 8) or one of the second metal compound layers 210b2 (FIG. 7).

The first or second metal compound layers 210b1 or 210b2 is preferably made of either TiC or VC.

When a compound semiconductor substrate wherein Si single crystal is used as a substrate, as in the present embodiment, is used as a light emitting device, a well-known light emitting structure is usually formed on the Si single crystal substrate (not illustrated).

In the case of such a structure, the direction in which the structure is to emit light as a light emitting device is the direction of the laminating of the layers in the compound semiconductor substrate (β direction in FIGS. 7 to 9). However, light rays from the light emitting structure are emitted not only in the above-mentioned light emitting direction (the laminating direction β) but also the direction opposite to the light emitting direction (that is, the direction opposite to the laminating direction β).

In order for the structure in this case to make the light emitting efficiency high as a light emitting device, it is preferred to lay a reflective layer for reflecting light advancing in the opposite direction so as to advance in the light emitting direction (the laminating direction β) beneath the light emitting structure, that is, in the laminate structure of the compound semiconductor substrate.

For reference, a metal compound layer made of any one of TiC, TiN, VC and VN has a higher function as a reflective layer (reflectivity) than the layer made of 3C—SiC. This is because 3C—SiC has a band gap of 2.2 eV and absorbs visible rays, which is different from TiC, TiN, VC and VN, which are each a metal compound. Out of TiC, TiN, VC and VN, TiC and VC have a higher function as a reflective layer (reflectivity) than TiN and VN.

Accordingly, when at least the topmost layer α, which functions as a reflective layer and contacts the second intermediate layer 220 is made of the first intermediate layer 210 is made of any one of TiC, TiN, VC and VN, more preferably either TiC or VC, the light emitting efficiency and the luminance can be further improved in the case of using this compound semiconductor substrate as a light emitting device.

Since the compound semiconductor substrate according to the present embodiment has the first intermediate layer 210 as described above, the nitride semiconductor single crystal layer 230 can be made thick within such a limitation that cracks, crystal defects or the like is not generated in the layer 230. When the nitride semiconductor single crystal layer 230 is made thick, the crystallinity of the layer itself can be improved.

In the embodiment, the number of the laminated layers in the first intermediate layer 210 is appropriately designed or modified in accordance with the thickness of the second intermediate layer 220 and the nitride semiconductor single crystal layer 230, and others. The film thickness of the nitride semiconductor single crystal layer 230 not permitting cracks, crystal defects or the like to be generated in the layer 230 cannot be specified without reservation since the film thickness depends on the number of the laminated layers in the first intermediate layer 210, and the thickness of the second intermediate layer 220 and the nitride semiconductor single crystal layer 230. The film thickness can be made into a large value of at most about 8.0 μm.

### EXAMPLES

The invention will be specifically described by way of the following examples; however, the invention is not limited by the examples.

### Example 1

The compound semiconductor substrate (shown in FIG. 1) described as the embodiment was produced by the following process:

A conductive n-type Si single crystal substrate 100 produced by the CZ method and having a crystal plane orientation {111}, a carrier concentration of 10¹⁸/cm³ and a thickness of 500 μm was subjected to thermal treatment at 1000° C. in a hydrogen atmosphere to clean its surfaces.

Next, biscyclopentadienylvanadium and propane were supplied onto the Si single crystal substrate 100 while the temperature of the substrate was set to 1150° C., so as to form a VC layer of 5 nm thickness, as a first metal compound layer 110a, thereon. Furthermore, tetrachlorotitanium and propane were supplied onto the first metal compound layer 110a while the substrate temperature was kept at the same temperature, so as to form a TiC layer of 5 nm thickness, as a second metal compound layer 110b, thereon. The formations were repeated to form a first intermediate layer 110 wherein 50 layers 110a were alternated with 50 layers 110b, the total number of the layers being 100. The formed topmost layer α was one of the TiC layers.

Next, trimethylaluminum and ammonia were used as starting gases to form a hexagonal AlN layer of 5 nm thickness, as a second intermediate layer 120, on the first intermediate layer 110 at a substrate temperature of 1100° C.

Furthermore, trimethylgallium and ammonia were used as starting gases to form a hexagonal GaN single crystal layer of 5 μm thickness, as a compound semiconductor single crystal layer 130, on the second intermediate layer 120 at a substrate temperature of 1000° C.

The thicknesses of the first intermediate layer 110, the second intermediate layer 120 and the compound semiconductor layer 130 were adjusted by the flow rates of the starting gases and periods for the thermal treatments.

The surface of the compound semiconductor single crystal layer 130 of the compound semiconductor substrate produced by the above-mentioned process was analyzed by X-rays, so as to check the generation situation of cracks, crystal defects or the like.

As a result, no crack was observed. The index of the generated crystal defects was restrained into a value lower than 10⁸/cm².

### Example 2

A compound semiconductor substrate was produced in the same way as in Example 1 except that the first metal compound layers 110a were rendered TiC layers and the second metal compound layers 110b were rendered VC layers. The formed topmost layer α was one of the VC layers.

The surface of the compound semiconductor single crystal layer 130 of the compound semiconductor substrate produced by the above-mentioned process was analyzed by X-rays, so as to check the generation situation of cracks, crystal defects or the like.

As a result, no crack was observed. The index of the generated crystal defects was restrained into a value lower than 10⁸/cm².

### Example 3

A compound semiconductor substrate was produced in the same way as in Example 1 except that the first metal compound layers 11a were rendered TiN layers and the second metal compound layers 110a were rendered VN layers. The formed topmost layer α was one of the VN layers.

The surface of the compound semiconductor single crystal layer 130 of the compound semiconductor substrate produced by the above-mentioned process was analyzed by X-rays, so as to check the generation situation of cracks, crystal defects or the like.

As a result, no crack was observed. The index of the generated crystal defects was restrained into a value lower than 10⁸/cm².

### Example 4

A compound semiconductor substrate was produced in the same way as in Example 1 except that the first metal compound layers 110a were rendered VN layers and the second metal compound layers 110a were rendered TiN layers. The formed topmost layer α was one of the TiN layers.

The surface of the compound semiconductor single crystal layer 130 of the compound semiconductor substrate produced by the above-mentioned process was analyzed by X-rays, so as to check the generation situation of cracks, crystal defects or the like.

As a result, no crack was observed. The index of the generated crystal defects was restrained into a value lower than 10⁸/cm².

### Example 5

A compound semiconductor substrate was produced in the same way as in Example 3 except that only the topmost layer α was rendered a TiC layer.

The surface of the compound semiconductor single crystal layer 130 of the compound semiconductor substrate produced by the above-mentioned process was analyzed by X-rays, so as to check the generation situation of cracks, crystal defects or the like.

As a result, no crack was observed. The index of the generated crystal defects was restrained into a value lower than 10⁸/cm².

### Example 6

A compound semiconductor substrate was produced in the same way as in Example 3 except that only the topmost layer α was rendered a VC layer.

The surface of the compound semiconductor single crystal layer 130 of the compound semiconductor substrate produced by the above-mentioned process was analyzed by X-rays, so as to check the generation situation of cracks, crystal defects or the like.

As a result, no crack was observed. The index of the generated crystal defects was restrained into a value lower than 10⁸/cm².

### Comparative Example 1

A compound semiconductor substrate was produced in the same way as in Example 1 except that the first intermediate layer 110 was formed to have a bi-layered structure made only of one of the first metal compound layers 110a and one of the second metal compound layers 110b.

The surface of the compound semiconductor single crystal layer 130 of the compound semiconductor substrate produced by the above-mentioned process was analyzed by X-rays, so as to check the generation situation of cracks, crystal defects or the like.

As a result, cracks were observed in the entire surface. The index of the generated crystal defects was about 10¹¹/cm².

### Comparative Example 2

A compound semiconductor substrate was produced in the same way as in Example 1 except that the first intermediate layer 110 was changed to a layer made only of the second metal compound layers 110b (TiC layers) and the number of the layers 110b was changed to 100 (thickness: 500 nm).

The surface of the compound semiconductor single crystal layer 130 of the compound semiconductor substrate produced by the above-mentioned process was analyzed by X-rays, so as to check the generation situation of cracks, crystal defects or the like.

As a result, cracks were slightly less generated than in Comparative Example 1, but were observed in the entire surface. The index of the generated crystal defects was about 10¹¹/cm².

### Example 7

The compound semiconductor substrate (shown in FIG. 3) described as the embodiment was produced by the following process:

A conductive n-type Si single crystal substrate 100 produced by the CZ method and having a crystal plane orientation {111}, a carrier concentration of 10¹⁸/cm³ and a thickness of 500 μm was subjected to thermal treatment at 1000° C. in a hydrogen atmosphere to clean its surfaces.

Next, propane was supplied onto the Si single crystal substrate 100 and the temperature of the substrate was set to 1150° C., so as to carbonize one of the surfaces of the Si single crystal substrate 100. Thereafter, propane and silane were supplied thereto, so as to form a 3C—SiC single crystal layer 150 of 20 nm thickness.

Thereafter, under the same conditions as in Example 1, a first intermediate layer 110, a second intermediate layer 120 and a nitride semiconductor single crystal layer 130 were each formed on the 3C—SiC single crystal layer 150.

The surface of the compound semiconductor single crystal layer 130 of the compound semiconductor substrate produced by the above-mentioned process was analyzed by X-rays, so as to check the generation situation of cracks, crystal defects or the like.

As a result, no crack was observed. The index of the generated crystal defects was restrained into a value lower than 10⁸/cm².

### Example 8

The compound semiconductor substrate (shown in FIG. 5) described as the embodiment was produced by the following process:

A conductive n-type Si single crystal substrate 200 produced by the CZ method and having a crystal plane orientation {111}, a carrier concentration of 10¹⁸/cm³ and a thickness of 500 μm was subjected to thermal treatment at 1000° C. in a hydrogen atmosphere to clean its surfaces.

Next, propane was supplied onto the Si single crystal substrate 100 and the temperature of the substrate was set to 1150° C., so as to carbonize one of the surfaces of the Si single crystal substrate 200. Thereafter, propane and silane were supplied thereto, so as to form a 3C—SiC single crystal layer 210a of 20 nm thickness. Subsequently, at the same substrate temperature, tetrachlorotitanium and propane were supplied onto the 3C—SiC single crystal layer 210a, so as to form a TiC layer of 20 nm thickness, as a metal compound layer 210b. The formations were repeated to form a first intermediate layer 210 wherein 50 layers 210a were alternated with 50 layers 210b, the total number of the layers being 100. The topmost layer α thereof was one of the TiC layers.

Next, trimethylaluminum and ammonia were used as starting gases to form a hexagonal AlN layer of 5 nm thickness, as a second intermediate layer 220, on the first intermediate layer 210 at a substrate temperature of 1100° C.

Furthermore, trimethylgallium and ammonia were used as starting gases to form a hexagonal GaN single crystal layer of 5 μm thickness, as a compound semiconductor single crystal layer 230, on the second intermediate layer 220 at a substrate temperature of 1000° C.

The thicknesses of the first intermediate layer 210, the second intermediate layer 220 and the compound semiconductor layer 230 were adjusted by the flow rates of the starting gases and periods for the thermal treatments.

The surface of the compound semiconductor single crystal layer 230 of the compound semiconductor substrate produced by the above-mentioned process was analyzed by X-rays, so as to check the generation situation of cracks, crystal defects or the like.

As a result, cracks were hardly observed. The index of the generated crystal defects was restrained into a value lower than 10⁸/cm².

### Example 9

A compound semiconductor substrate was produced in the same way as in Example 8 except that each of the metal compound layers 210b was rendered a VC layer of 5 nm thickness. The formation of the VC layers was performed by setting the substrate temperature of the Si single crystal substrate 200 to 1150° C. and supplying biscyclopentadienylvanadium and propane. The formed topmost layer α was one of the VC layers.

The surface of the compound semiconductor single crystal layer 230 of the compound semiconductor substrate produced by the above-mentioned process was analyzed by X-rays, so as to check the generation situation of cracks, crystal defects or the like.

As a result, cracks were hardly observed. The index of the generated crystal defects was restrained into a value lower than 10⁸/cm².

### Example 10

A compound semiconductor substrate was produced in the same way as in Example 8 except that each of the metal compound layers 210b was rendered a TiN layer of 10 nm thickness. The formation of the TiN layers was performed by setting the substrate temperature of the Si single crystal substrate 200 to 1150° C. and supplying tetrachlorotitanium and ammonia. The formed topmost layer α was one of the TiN layers.

The surface of the compound semiconductor single crystal layer 230 of the compound semiconductor substrate produced by the above-mentioned process was analyzed by X-rays, so as to check the generation situation of cracks, crystal defects or the like.

As a result, cracks were hardly observed. The index of the generated crystal defects was restrained into a value lower than 10⁸/cm².

### Example 11

A compound semiconductor substrate was produced in the same way as in Example 8 except that each of the metal compound layers 210b was rendered a VN layer of 5 nm thickness. The formation of the VN layers was performed by setting the substrate temperature of the Si single crystal substrate 200 to 1150° C. and supplying biscyclopentadienylvanadium and ammonia. The formed topmost layer was one of the VN layers.

The surface of the compound semiconductor single crystal layer 230 of the compound semiconductor substrate produced by the above-mentioned process was analyzed by X-rays, so as to check the generation situation of cracks, crystal defects or the like.

As a result, cracks were hardly observed. The index of the generated crystal defects was restrained into a value lower than 10⁸/cm².

### Example 12

A compound semiconductor substrate was produced in the same way as in Example 8 except that about the first intermediate layer 210, the first to the 99th layers thereof were formed but the 100th layer thereof was not formed. Thus, the formed topmost layer α was one of the 3C—SiC single crystal layers.

The surface of the compound semiconductor single crystal layer 230 of the compound semiconductor substrate produced by the above-mentioned process was analyzed by X-rays, so as to check the generation situation of cracks, crystal defects or the like.

As a result, cracks were hardly observed. The index of the generated crystal defects was restrained into a value lower than 10⁸/cm².

### Comparative Example 3

A compound semiconductor substrate was produced in the same way as in Example 8 except that the first intermediate layer 210 was formed to have a bi-layered structure made only of one of the 3C—SiC single crystal layers 210a and one of the metal compound layers 210b.

The surface of the compound semiconductor single crystal layer 230 of the compound semiconductor substrate produced by the above-mentioned process was analyzed by X-rays, so as to check the generation situation of cracks, crystal defects or the like.

As a result, cracks were observed in the entire surface. The index of the generated crystal defects was about 10¹¹/cm².

### Example 13

The compound semiconductor substrate (shown in FIG. 7) described as the embodiment was produced by the following process:

A conductive n-type Si single crystal substrate 200 produced by the CZ method and having a crystal plane orientation {111}, a carrier concentration of 10¹⁸/cm³ and a thickness of 500 μm was subjected to thermal treatment at 1000° C. in a hydrogen atmosphere to clean its surfaces.

Next, propane was supplied onto the Si single crystal substrate 100 and the temperature of the substrate was set to 1150° C., so as to carbonize one of the surfaces of the Si single crystal substrate 200. Thereafter, propane and silane were supplied thereto, so as to form a 3C—SiC single crystal layer 210a of 20 nm thickness. Subsequently, the substrate temperature of the Si single crystal substrate 220 was set to 1150° C., and tetrachlorotitanium and propane were supplied onto the 3C—SiC single crystal layer 210a, so as to form a TiC layer of 20 nm thickness, as a first metal compound layer 210b1, onto the layer 210a. Subsequently, biscyclopentadienylvanadium and propane were supplied onto the first metal compound layer 210b1 so as to form a VC layer of 5 nm thickness, as a second metal compound layer 210b2, onto the layer 210b1. The formations were repeated to form a first intermediate layer 210 wherein 33 layers 210a, 33 layers 210b1 and 33 layers 210b2 were alternately laminated, the total number of the layers being 99. About the others, the same manner as in Example 8 was performed.

The surface of the compound semiconductor single crystal layer 230 of the compound semiconductor substrate produced by the above-mentioned process was analyzed by X-rays, so as to check the generation situation of cracks, crystal defects or the like.

As a result, cracks were hardly observed. The index of the generated crystal defects was restrained into a value lower than 10⁸/cm².

### Comparative Example 4

A compound semiconductor substrate was produced in the same way as in Example 13 except that the first metal compound layers 210b1 and the second metal compound layers 210b2 were each rendered a TiC layer.

The surface of the compound semiconductor single crystal layer 230 of the compound semiconductor substrate produced by the above-mentioned process was analyzed by X-rays, so as to check the generation situation of cracks, crystal defects or the like.

As a result, a better result was obtained than in Comparative Example 3, but cracks and crystal defects were substantially to the same degree as in Comparative Example 3.

### Comparative Example 5

A compound semiconductor substrate was produced in the same way as in Example 13 except that the first intermediate layer 210 was changed to a layer made only of one of the 3C—SiC single crystal layers 210a, one of the first metal compound layers 210b1 and one of the second metal compound layers 210b2, the total number of the layers being three.

The surface of the compound semiconductor single crystal layer 230 of the compound semiconductor substrate produced by the above-mentioned process was analyzed by X-rays, so as to check the generation situation of cracks, crystal defects or the like.

As a result, cracks were observed in the entire surface. The index of the generated crystal defects was about 10¹¹/cm².

### Examples About Light Emitting Devices

Each of the compound semiconductor substrates produced in Examples 1 to 7 was used, and a well-known light emitting structure was formed on a surface thereof. The formed samples were evaluated about the luminance (cd/mm²) thereof (Table 1). In Table 1, the luminance of each of the samples is represented as the ratio thereof to the luminance of the sample derived from Example 3 (the laminate composed of the TiN layers alternated with the VN layers; the topmost layer: one of the VN layers).

TABLE 1

| | Luminance |
|---|---|
| | (the ratio thereof to the luminance of |
| | the sample derived from Example 3) |
| Example 1 | 1.60 |
| Example 2 | 1.65 |
| Example 3 | 1.00 |
| Example 4 | 1.00 |
| Example 5 | 1.55 |
| Example 6 | 1.50 |
| Example 7 | 1.67 |

As shown in Table 1, in Examples 5 and 6, wherein only the topmost layer α was the TiC layer or VC layer, the luminance was larger than in Examples 3 and 4, wherein only the TiN layers and the VN layers were laminated. Moreover, in Examples 1 and 2, wherein only the TiC layers and the VC layers were laminated, the luminance was larger than in Examples 5 and 6. In Example 7, wherein the 3C—SiC single crystal layers were interposed, the luminance was somewhat larger than in Examples 1 and 2.

Each of the compound semiconductor substrates produced in Examples 8 to 12 was used, and a well-known light emitting structure was formed on a surface thereof. The formed samples were evaluated about the luminance (cd/mm²) thereof. The results are shown in Table 2. In Table 2, the luminance of each of the samples is represented as the ratio thereof to the luminance of the sample derived from Example 12.

TABLE 2

| | Luminance |
|---|---|
| | (the ratio thereof to the luminance of |
| | the sample derived from Example 12) |
| Example 8 | 1.40 |
| Example 9 | 1.45 |
| Example 10 | 1.20 |
| Example 11 | 1.25 |
| Example 12 | 1.00 |

As shown in Table 2, in Examples 10 and 11, wherein the topmost layer α was made of TiN or VN, the luminance was better than in Example 12, wherein the topmost layer α was made of 3C—SiC. In Examples 8 and 9, wherein the topmost layer α was made of TiC or VC, the luminance was better than in Examples 10 and 11, wherein the topmost layer α was made of TiN or VN.

1. A compound semiconductor substrate, comprising:
a first intermediate layer formed on a Si single crystal substrate having a crystal plane orientation of a {111} plane, wherein the first intermediate layer comprises a first metal compound layer made of any one of TiC, TiN, VC and VN and a second metal compound layer made of any one of compounds which are different from the compound of the first metal compound layer out of TiC, TiN, VC and VN, the first metal compound layer and the second metal compound layer are laminated in this order alternately each other over the Si single crystal substrate, and the topmost layer of the resultant laminate is made of one of the first metal compound layers, or one of the second metal compound layers;
a second intermediate layer formed on the first intermediate layer and made of In_{w}GaₓAl_{1-w-x}N single crystal wherein 0≦w<1, 0≦x<1, and w+x<1; and
a nitride semiconductor single crystal layer formed on the second intermediate layer and made of In_{y}Ga_{z}Al_{1-y-z}N single crystal wherein 0≦y<1, 0≦z<1, and y+z<1.

2. A compound semiconductor substrate, comprising:
a 3C—SiC single crystal layer formed on a Si single crystal substrate having a crystal plane orientation of a {111} plane;
a first intermediate layer formed on the 3C—SiC single crystal layer, wherein the first intermediate layer comprises a first metal compound layer made of any one of TiC, TiN, VC and VN and a second metal compound layer made of any one of compounds which are different from the compound of the first metal compound layer out of TiC, TiN, VC and VN, the first metal compound layer and the second metal compound layer are laminated in this order alternately each other over the Si single crystal substrate, and the topmost layer of the resultant laminate is made of one of the first metal compound layers, or one of the second metal compound layers;
a second intermediate layer formed on the first intermediate layer and made of In_{w}GaₓAl_{1-w-x}N single crystal wherein 0≦w<1, 0≦x<1, and w+x<1; and
a nitride semiconductor single crystal layer formed on the second intermediate layer and made of In_{y}Ga_{z}Al_{1-y-z}N single crystal wherein 0≦y<1, 0≦z<1, and y+z<1.

3. The compound semiconductor substrate according to claim 1, wherein the topmost layer is made of either TiC or VC.

4. The compound semiconductor substrate according to claim 1, wherein the first metal compound layers are made of TiC, and the second metal compound layers are made of VC.

5. A compound semiconductor substrate, comprising:
a first intermediate layer formed on a Si single crystal substrate having a crystal plane orientation of a {111} plane, wherein the first intermediate layer comprises a 3C—SiC single crystal layer and a metal compound layer made of any one of TiC, TiN, VC and VN, the 3C—SiC single crystal layer and the metal compound layer are laminated in this order alternately each other over the Si single crystal substrate, and the topmost layer of the resultant laminate is made of one of the 3C—SiC single crystal layers, or one of the metal compound layers;
a second intermediate layer formed on the first intermediate layer and made of In_{w}GaₓAl_{1-w-x}N single crystal wherein 0≦w<1, 0≦x<1, and w+x<1; and
a nitride semiconductor single crystal layer formed on the second intermediate layer and made of In_{y}Ga_{z}Al_{1-y-z}N single crystal wherein 0≦y<1, 0≦z<1, and y+z<1.

6. The compound semiconductor substrate according to claim 5, wherein the topmost layer is the metal compound layers.

7. The compound semiconductor substrate according to claim 6, wherein the metal compound layers are made of either TiC or VC.

8. A compound semiconductor substrate, comprising:
a first intermediate layer formed on a Si single crystal substrate having a crystal plane orientation of a {111} plane, wherein the first intermediate layer comprises a 3C—SiC single crystal layer, a first metal compound layer made of any one of TiC, TiN, VC and VN, and a second metal compound layer made of any one of compounds which are different from the compound of the first metal compound layer out of TiC, TiN, VC and VN, the 3C—SiC single crystal layer, the first metal compound layer and the second metal compound layer are laminated in this order alternately to one another over the Si single crystal substrate, and the topmost layer of the resultant laminate is made of one of the 3C—SiC single crystal layers, one of the first metal compound layers, or one of the second metal compound layers;
a second intermediate layer formed on the first intermediate layer and made of In_{w}GaₓAl_{1-w-x}N single crystal wherein 0≦w<1, 0≦x<1, and w+x<1; and
a nitride semiconductor single crystal layer formed on the second intermediate layer and made of In_{y}Ga_{z}Al_{1-y-z}N single crystal wherein 0≦y<1, 0≦z<1, and y+z<1.

9. The compound semiconductor substrate according to claim 8, wherein the topmost layer is one of the first metal compound layers, or one of the second metal compound layers.

10. The compound semiconductor substrate according to claim 9, wherein the first metal compound layers or the second metal compound layers are made of either TiC or VC.

11. The compound semiconductor substrate according to claim 2, wherein the topmost layer is made of either TiC or VC.

12. The compound semiconductor substrate according to claim 2, wherein the first metal compound layers are made of TiC, and the second metal compound layers are made of VC.
